(19) United States
(12) Patent Application Publication
(10) Pub. No.: US 2026/0182294 A1
(43) Pub. Date: Jun. 25, 2026

(54) SEMICONDUCTOR EQUIPMENT AND PRESSURE CONTROL METHOD THEREOF

(71) Applicant: Tokyo Electron Limited, TOKYO (JP)

(72) Inventors: Fu Chieh HSU, Hsinchu City (TW); CHUN HUNG HUNG, Hsinchu City (TW); CHENG HSIUNG LEE, Hsinchu City (TW); CHI MING KUO, Hsinchu City (TW); CHUN HUNG HUNG, Hsinchu City (TW)

(21) Appl. No.: 19/416,368

(22) Filed: Dec. 11, 2025

Related U.S. Application Data
(60) Provisional application No. 63/738,358, filed on Dec. 23, 2024.

(51) Int. Cl. H10P 72/00

(52) U.S. Cl. CPC H10P 72/0402

(57) ABSTRACT

A semiconductor equipment and a pressure control method are provided. The semiconductor equipment includes a high-pressure processing apparatus and a pressure balancing element. The high-pressure processing apparatus includes an inner chamber and an outer chamber. The inner chamber is configured to accommodate a reaction gas at a first pressure. The outer chamber surrounds the inner chamber and is configured to accommodate an inert gas at a second pressure. The outer chamber is isolated from the inner chamber in the high-pressure processing apparatus. The pressure balancing element is connected to the inner chamber through a first pipe, connected to the outer chamber through a second pipe isolated from the first pipe, and is configured to balance the first pressure and the second pressure when a pressure difference between the first pressure and the second pressure is greater than a predetermined pressure difference.

### CROSS-REFERENCE TO RELATED APPLICATIONS

This application claims priority to U.S. provisional application No. 63/738,358, filed on Dec. 23, 2024, the entire content of which is incorporated herein by reference.

### TECHNICAL FIELD

The present disclosure relates to a semiconductor equipment and a pressure control method, and in particular, to a semiconductor equipment including a pressure balancing element and a pressure control method for the semiconductor equipment.

### BACKGROUND

High-pressure thermal treatment offers significant advantages for enhancing the performance of semiconductor components in advanced nanotechnology. However, the flammability and leakage risks associated with reactive gases under high pressure present serious safety challenges for high-pressure thermal treatment equipment, particularly in handling pressure imbalances between chambers. Current equipment relies on electronic signals and components to detect and control the internal pressure of the chambers. Yet, these electronic signals are vulnerable to distortion or loss due to external factors such as unstable electrical current or electromagnetic induction, which can cause component failure or malfunction. Such failures hinder timely pressure control and may result in damage to the chambers. Consequently, there is an urgent need for a safer, more reliable, and cost-effective pressure control mechanism to address these issues.

### SUMMARY

In some embodiments, a semiconductor equipment includes a high-pressure processing apparatus and a pressure balancing element. The high-pressure processing apparatus includes an inner chamber and an outer chamber. The inner chamber is configured to accommodate a reaction gas at a first pressure. The outer chamber surrounds the inner chamber and is configured to accommodate an inert gas at a second pressure. The outer chamber is isolated from the inner chamber in the high-pressure processing apparatus. The pressure balancing element is connected to the inner chamber through a first pipe, connected to the outer chamber through a second pipe isolated from the first pipe, and is configured to balance the first pressure and the second pressure when a pressure difference between the first pressure and the second pressure is greater than a predetermined pressure difference.

In some embodiments, a pressure control method includes: providing a high-pressure processing apparatus including an inner chamber configured to accommodate a reaction gas at a first pressure and an outer chamber surrounding the inner chamber and configured to accommodate an inert gas at a second pressure, wherein the outer chamber is isolated from the inner chamber in the high-pressure processing apparatus; connecting the inner chamber and the outer chamber by a pressure balancing element; and balancing the first pressure and the second pressure upon a pressure difference between the first pressure and the second pressure received by the pressure balancing element is greater than a predetermined value.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a schematic view of a semiconductor equipment according to some embodiments of the present disclosure.

FIG. 2 illustrates an action view of a pressure balancing element of FIG. 1.

FIG. 3 illustrates an action view of a detection element of FIG. 2.

FIG. 4 illustrates an assembly view of a detection element and a pressure balancing element according to some embodiments of the present disclosure.

FIG. 5 illustrates an action view of a detection element of FIG. 4.

FIG. 6 illustrates a schematic view of a semiconductor equipment according to some embodiments of the present disclosure.

FIGS. 7A to 7B illustrate action views of a pressure balancing element of FIG. 6.

FIG. 8 illustrates a schematic view of a semiconductor equipment according to some embodiments of the present disclosure.

FIG. 9 illustrates a schematic view of one or more stages of some embodiments of a pressure control method according to the present disclosure.

### DETAILED DESCRIPTION

The components, values, operations, materials and configurations in the following disclosure are merely embodiments or examples and are not intended to be limiting. For example, a first element being formed over or on a second element may include different implementations. The first element and the second element may be in direct contact. Alternatively, the first element and the second element may not be in direct contact, and an additional element between the first element and the second element may be included.

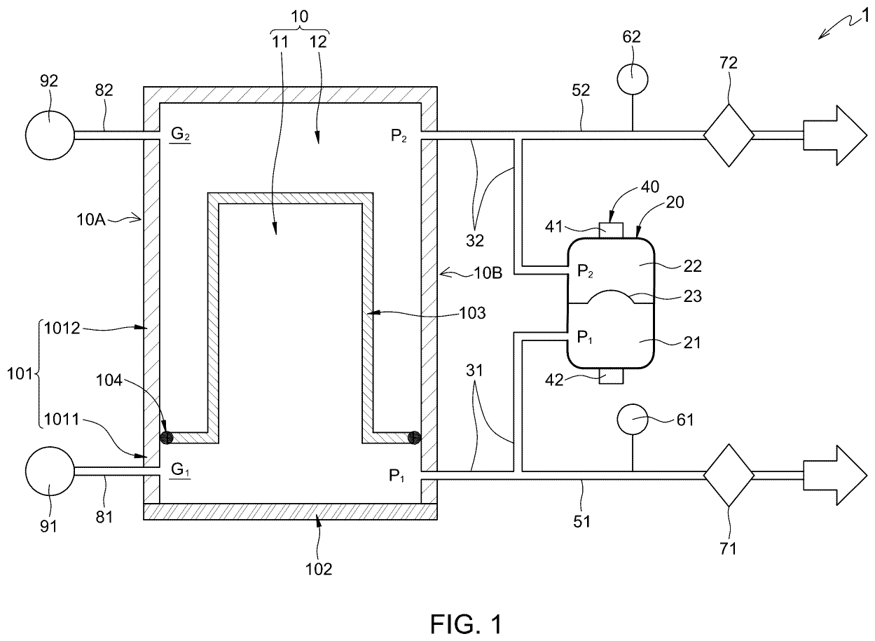

FIG. 1 illustrates a schematic view of a semiconductor equipment 1 according to some embodiments of the present disclosure. The semiconductor equipment 1 of FIG. 1 may include a high-pressure processing apparatus 10, a pressure balancing element 20, a first pipe 31, a second pipe 32, at least one detection element 40, a first exhaust pipe 51, a second exhaust pipe 52, a first pressure transmitting element 61, a second pressure transmitting element 62, a first pressure control element 71, a second pressure control element 72, a reaction gas supplying pipe 81, an inert gas supplying pipe 82, a first booster element 91, and a second booster element 92.

The high-pressure processing apparatus 10 may be a high-pressure annealing apparatus for processing semiconductor elements. In some embodiments, as shown in FIG. 1, the high-pressure processing apparatus 10 may include a housing 101, a lid 102, a cover 103, an inner chamber 11, an outer chamber 12, and at least one sealing element 104. The housing 101 may be a metal outer cavity. The housing 101 may include a metal material such as stainless steel. The lid 102 may be combined with the housing 101 to constitute a closed container. The lid 102 may include a metal material such as stainless steel. The lid 102 may be disposed under the cover 103. The lid 102 may be configured to cover an opening of the housing 101. The lid 102 may be also referred to as “a cap”.

The cover 103 may be disposed in the housing 101. The cover 103 may be a non-metallic inner cavity cover such as a quartz tube or a quartz vessel. In some embodiments, the high-pressure processing apparatus 10 may have an inlet end 10A (or an inlet side) and an outlet end 10B (or an outlet side). The outlet end 10B is opposite to the inlet end 10A. For example, the outlet end 10B may be the right side of the high-pressure processing apparatus 10, and the inlet end 10A may be the left side of the high-pressure processing apparatus 10.

The inner chamber 11 (e.g., inner cavity or inner accommodating space) may be defined by a first portion 1011 of the housing 101, the lid 102 and the cover 103. The first portion 1011 of the housing 101 may be a lower portion of the housing 101, and may be located lower than the cover 103 and the sealing element 104. The inner chamber 11 may be configured to accommodate a reaction gas G₁ at a first pressure P₁. In some embodiments, the reaction gas G₁ may include but is not limited to, H₂, F₂, NH₃, or Cl₂. In some embodiments, the inner chamber 11 may also be referred to as “reaction gas zone.”

The outer chamber 12 (e.g., outer cavity or outer accommodating space) may be defined by a second portion 1012 of the housing 101 and the cover 103. The outer chamber 12 may surround the inner chamber 11. The second portion 1012 of the housing 101 may be an upper portion of the housing 101, and may be located higher than the sealing element 104. In some embodiments, the outer chamber 12 may be isolated from the inner chamber 11 through the cover 103 and the sealing element 104 in the high-pressure processing apparatus 10. The outer chamber 12 may be configured to accommodate an inert gas G₂ at a second pressure P₂. In some embodiments, the inert gas G₂ may include but is not limited to, CO₂, N₂, He, Ar, or a mixture thereof. In some embodiments, the outer chamber 12 may also be referred to as “inert gas zone.”

The at least one sealing element 104 may be disposed between the housing 101 and the cover 103 to isolate the inner chamber 11 from the outer chamber 12 so to prevent the communication between the inner chamber 11 and the outer chamber 12. In some embodiments, the high-pressure processing apparatus 10 may further include a heater (not shown) and a cooler (not shown). The heater may be disposed around the cover 103 to heat the cover 103 to make the temperature in the inner chamber 11 reach the process temperature. The heater may surround an upper end of the cover 103. The cooler may be disposed around the housing 101 to adjust or control the temperature in the inner chamber 11 and the temperature in the outer chamber 12. The cooler may be disposed outside the housing 101, and may surround an upper end of the housing 101.

The pressure balancing element 20 may be located at or located adjacent to the outlet end 10B of the high-pressure processing apparatus 10. The pressure balancing element 20 may be connected to the inner chamber 11 through the first pipe 31 and to the outer chamber 12 through the second pipe 32. In some embodiments, the second pipe 32 may be isolated from the first pipe 31. The pressure balancing element 20 may be configured to balance the first pressure P₁ and the second pressure P₂ when a pressure difference between the first pressure P₁ and the second pressure P₂ is greater than a predetermined pressure difference. In some embodiments, the pressure balancing element 20 may balance the first pressure P₁ and the second pressure P₂ upon receiving the pressure difference between the first pressure P₁ and the second pressure P₂.

In some embodiments, the pressure balancing element 20 may have a pressure tolerance value less than a pressure tolerance value of the inner chamber 11, less than a pressure tolerance value of the cover 103, and less than the predetermined pressure difference between the first pressure P₁ and the second pressure P₂. Therefore, the pressure balancing element 20 will be damaged earlier than the break of the inner chamber 11 and the break of the cover 103 when the pressure difference between the first pressure P₁ and the second pressure P₂ is greater than the pressure tolerance value of the pressure balancing element 20. In some situation, if the pressure balancing element 20 is damaged, the damaged pressure balancing element 20 may balance the first pressure P₁ and the second pressure P₂ by communicating the first pipe 31 with the second pipe 32 to prevent the cover 103 from breaking due to the large pressure difference between the first pressure P₁ and the second pressure P₂. That is, the pressure balancing element 20 may be a safety mechanism or an alarm mechanism configured to eliminate the excessive pressure difference between the first pressure P₁ and the second pressure P₂. In some embodiments, the pressure difference may be greater than or equal to 0.01 bar. In some embodiments, the pressure difference may be 0.01 to 0.1 bar, 0.01 to 1 bar, 0.01 to 10 bar, or 0.01 to 100 bar.

In some embodiments, as shown in FIG. 1, the pressure balancing element 20 may include a bursting disc. The pressure balancing element 20 (e.g., the bursting disc) may include a first space 21, a second space 22, and an isolation component 23. The first space 21 may be configured to receive the reaction gas G₁ at the first pressure P₁ through the first pipe 31. The second space 22 may be configured to receive the inert gas G₂ at the second pressure P₂ through the second pipe 32. The isolation component 23 may be disposed between the first space 21 and the second space 22, and may be configured to isolate the first space 21 from the second space 22 so as to prevent the communication between the first space 21 and the second space 22. In some embodiments, the isolation component 23 may be in disc, flake, or film form.

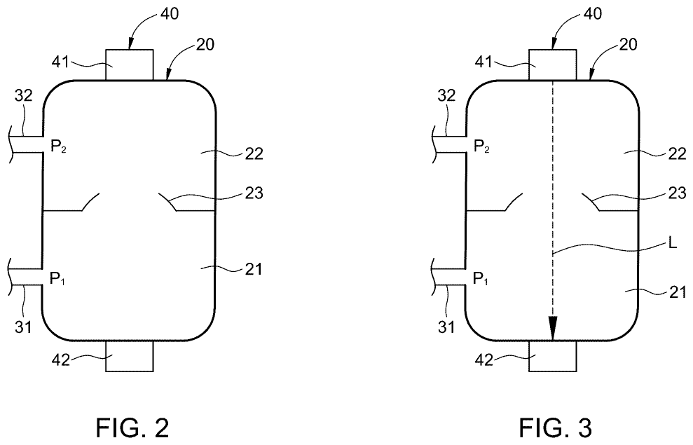

The isolation component 23 may have a pressure tolerance value less than the predetermined pressure difference between the first pressure P₁ and the second pressure P₂. As shown in FIG. 1, the current pressure difference between the current first pressure P₁ and the current second pressure P₂ is less than the pressure tolerance value of the isolation component 23. Thus, the isolation component 23 can sustain the current pressure difference, and can maintain its structure and shape. Meanwhile, the isolation component 23 is in an intact state. However, if the pressure difference between the current first pressure P₁ and the current second pressure P₂ increases to exceed the pressure tolerance value of the isolation component 23, the isolation component 23 will break as shown in FIG. 2. Meanwhile, the isolation component 23 is in a burst state or a break state.

FIG. 2 illustrates an action view of a pressure balancing element 20 of FIG. 1. As shown in FIG. 2, the isolation component 23 may burst when the pressure difference between the first pressure P₁ and the second pressure P₂ is greater than the pressure tolerance value of the isolation component 23. Thus, the first space 21 may communicate with the second space 22 to balance the first pressure P₁ and the second pressure P₂, resulting in P₁=P₂. For example, if the first pressure P₁ is greater than the second pressure P₂, the reaction gas G₁ in the first space 21 will enter the second space 22 through an opening of the isolation component 23. If the second pressure P₂ is greater than the first pressure P₁, the inert gas G₂ in the second space 22 will enter the first space 21 through the opening of the isolation component 23.

FIG. 3 illustrates an action view of a detection element 40 of FIG. 2. Referring to FIG. 1 and FIG. 3, the at least one detection element 40 may be disposed on the pressure balancing element 20. The at least one detection element 40 may be configured to detect the isolation component 23 of the pressure balancing element 20 (e.g., the bursting disc). In some embodiments, the isolation component 23 may include the intact state and the burst state. In some embodiments, the at least one detection element 40 may send an alarm signal to the high-pressure processing apparatus 10 upon detecting the burst state of the isolation component 23.

In some embodiments, as shown in FIG. 3, the at least one detection element 40 may include a photo interrupter. The photo interrupter may include an optical transmitter 41 and an optical receiver 42. When the isolation component 23 is in the intact state, the isolation component 23 may be disposed between the optical transmitter 41 and the optical receiver 42 to block light L transmitted from the optical transmitter 41 from reaching the optical receiver 42. In addition, when the optical receiver 42 can receive the light L transmitted from the optical transmitter 41, it indicates that the isolation component 23 is in the burst state. That is, the light L transmitted from the optical transmitter 41 can reach the optical receiver 42 through the opening of the isolation component 23. In some embodiments, when the isolation component 23 bursts, the detection element 40 will transmit an alarm signal to a control unit of the semiconductor equipment 1 to shut down the operation of the semiconductor equipment 1.

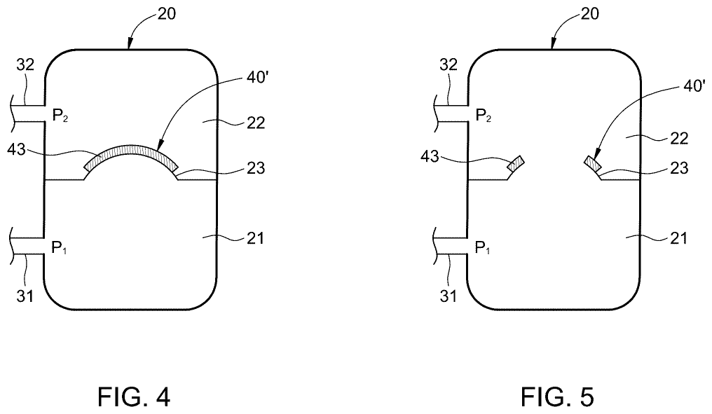

FIG. 4 illustrates an assembly view of a detection element 40′ and a pressure balancing element 20 according to some embodiments of the present disclosure. FIG. 5 illustrates an action view of a detection element 40′ of FIG. 4. In some embodiments, as shown in FIG. 4, the at least one detection element 40′ may include a circuit component 43. The circuit component 43 may be attached to the isolation component 23. Two end of the circuit component 43 may be electrically connected to an electronic device. As shown in FIG. 5, when the circuit component 43 is open-circuited, it indicates that the isolation component 23 is in the burst state. For example, the circuit component 43 may include at least one circuit layer on the isolation component 23. When the isolation component 23 bursts, the circuit layer of the circuit component 43 will break accordingly. Thus, the state of the isolation component 23 can be obtained by detecting the condition of the circuit layer of the circuit component 43.

Referring again to FIG. 1, the first exhaust pipe 51 may communicate with the first pipe 31 and be configured to exhaust the reaction gas G₁. In some embodiments, the first exhaust pipe 51 may also be utilized to recycle the reaction gas G₁. The second exhaust pipe 52 may communicate with the second pipe 32 and be configured to exhaust the inert gas G₂. In some embodiments, the second exhaust pipe 52 may also be utilized to recycle the inert gas G₂. In some embodiments, the second exhaust pipe 52 may be isolated from the first exhaust pipe 51.

The first pressure transmitting element 61 may be disposed on the first exhaust pipe 51. The first pressure transmitting element 61 may be configured to convert the first pressure P₁ of the reaction gas G₁ into a first electronic pressure signal. The second pressure transmitting element 62 may be disposed on the second exhaust pipe 52. The second pressure transmitting element 62 may be configured to convert the second pressure P₂ of the inert gas G₂ into a second electronic pressure signal. In some embodiments, the first pressure transmitting element 61 may also be referred to as the “first transducer.” The second pressure transmitting element 62 may also be referred to as the “second transducer.”

The first pressure control element 71 may be disposed on the first exhaust pipe 51 and configured to control the first pressure P₁. In some embodiments, the first pressure control element 71 may control the first pressure P₁ according to the first electronic pressure signal. The second pressure control element 72 may be disposed on the second exhaust pipe 52 and configured to control the second pressure P₂. In some embodiments, the second pressure control element 72 may control the second pressure P₂ according to the second electronic pressure signal.

The reaction gas supplying pipe 81 may be connected to the inner chamber 11 from an opposite direction to the first pipe 31. The reaction gas supplying pipe 81 may be connected to the first portion 1011 of the housing 101. The first booster element 91 may be disposed on the reaction gas supplying pipe 81 and configured to boost the first pressure P₁ of the reaction gas G₁. When the reaction gas G₁ is pressurized by the first booster element 91, it may flow through the reaction gas supplying pipe 81, the inner chamber 11, the first pipe 31, the pressure balancing element 20, the first exhaust pipe 51, the first pressure transmitting element 61, and the first pressure control element 71. In some embodiments, the first booster element 91 may work with the first pressure control element 71 to adjust the first pressure P₁.

The inert gas supplying pipe 82 may be connected to the outer chamber 12 from an opposite direction to the second pipe 32. The inert gas supplying pipe 82 may be connected to the second portion 1012 of the housing 101. The second booster element 92 may be disposed on the inert gas supplying pipe 82 and configured to boost the second pressure P₂ of the inert gas G₂. When the inert gas G₂ is pressurized by the second booster element 92, it may flow through the inert gas supplying pipe 82, the outer chamber 12, the second pipe 32, the pressure balancing element 20, the second exhaust pipe 52, the second pressure transmitting element 62, and the second pressure control element 72. In some embodiments, the second booster element 92 may work with the second pressure control element 72 to adjust the second pressure P₂.

In the embodiment illustrated in FIG. 1 to FIG. 5, the pressure balancing element 20 may balance the first pressure P₁ of the reaction gas G₁ and the second pressure P₂ of the inert gas G₂ upon receiving the pressure difference between the first pressure P₁ and the second pressure P₂ that is greater than the pressure tolerance value of the pressure balancing element 20, thereby preventing damage to the inner chamber 11 and the cover 103 caused by excessive pressure difference. Since the use cost of the pressure balancing element 20 is much lower than the repairing cost of the inner chamber 11 and the cover 103, even if the first pressure P₁ and the second pressure P₂ are balanced through the damage of the pressure balancing element 20 (e.g., the bursting disc) itself, it is still more economical than repairing the inner chamber 11 and the cover 103. Furthermore, the pressure balancing element 20 achieves the pressure balance between the first pressure P₁ and the second pressure P₂ by communicating the first pipe 31 with the second pipe 32. The reaction gas G₁ and the inert gas G₂ will be mixed in the pressure balancing process. The pressure balancing element 20 located at the outlet end 10B of the high-pressure processing apparatus 10 may prevent the mixture of the reaction gas G₁ and the inert gas G₂ from entering and contaminating the inner chamber 11. The pressure balancing element 20 may be a mechanical type device, which will not failure due to external factors (e.g., unstable electrical current and/or electromagnetic induction). Thus, the pressure difference between the inner chamber 11 and the outer chamber 12 can be controlled in time.

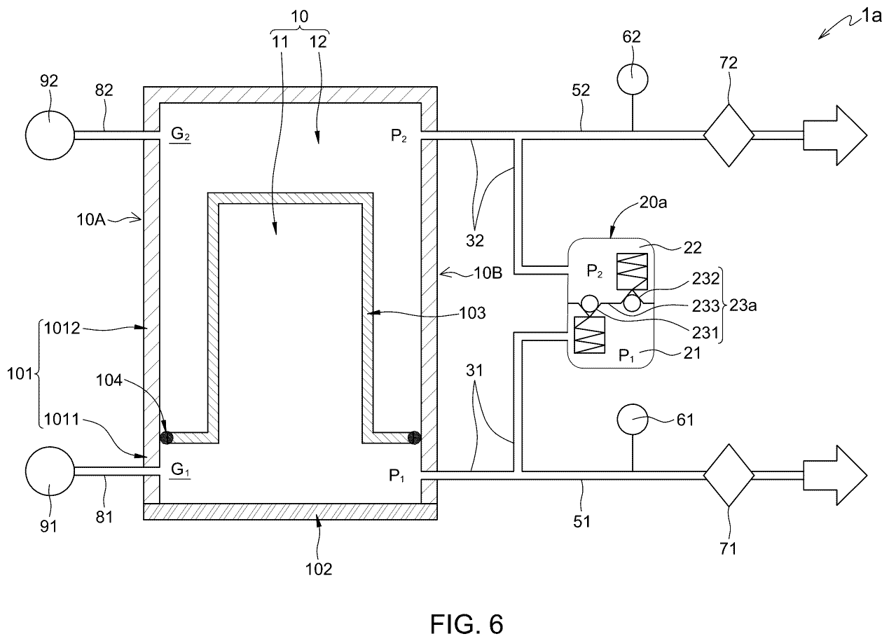

FIG. 6 illustrates a schematic view of a semiconductor equipment 1a according to some embodiments of the present disclosure. The semiconductor equipment 1a of FIG. 6 has a structure similar to the semiconductor equipment 1 of FIG. 1, except for a structure of the pressure balancing element 20a in FIG. 6. In some embodiments, as shown in FIG. 6, the pressure balancing element 20a may include a mechanical safety valve or a mechanical proportional valve. Therefore, the isolation component 23a of the pressure balancing element 20a may include a first valve portion 231, a second valve portion 232 and a separator 233. The first valve portion 231 may be configured to release pressure along a first direction. The second valve portion 232 may be configured to release pressure along a second direction contrary to the first direction. The separator 233 may be configured to define the first space 21 and the second space 22. In some embodiments, the separator 233 may have a first opening corresponding to the first valve portion 231 and a second opening corresponding to the second valve portion 232. The first space 21 may communicate the second space 22 through the first opening or the second opening. The first valve portion 231 may expose or close the first opening of the separator 233. The second valve portion 232 may expose or close the second opening of the separator 233.

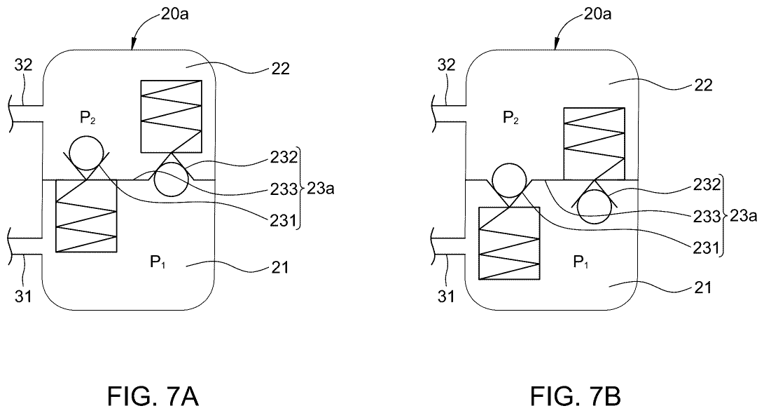

FIGS. 7A to 7B illustrate action views of the pressure balancing element 20a of FIG. 6. In some embodiments, as shown in FIG. 7A, the first valve portion 231 may be opened to expose the first opening of the separator 233 and release pressure when the pressure difference between the first pressure P₁ and the second pressure P₂ (e.g., P₁>P₂) is greater than a pressure tolerance value of the first valve portion 231. In some embodiments, as shown in FIG. 7B, the second valve portion 232 may be opened to expose the second opening of the separator 233 and release pressure when the pressure difference between the first pressure P₁ and the second pressure P₂ (e.g., P₁<P₂) is greater than a pressure tolerance value of the second valve portion 232. The opened first valve portion 231 or the opened second valve portion 232 may communicate the first space 21 with the second space 22 to balance the first pressure P₁ and the second pressure P₂, resulting in P₁=P₂.

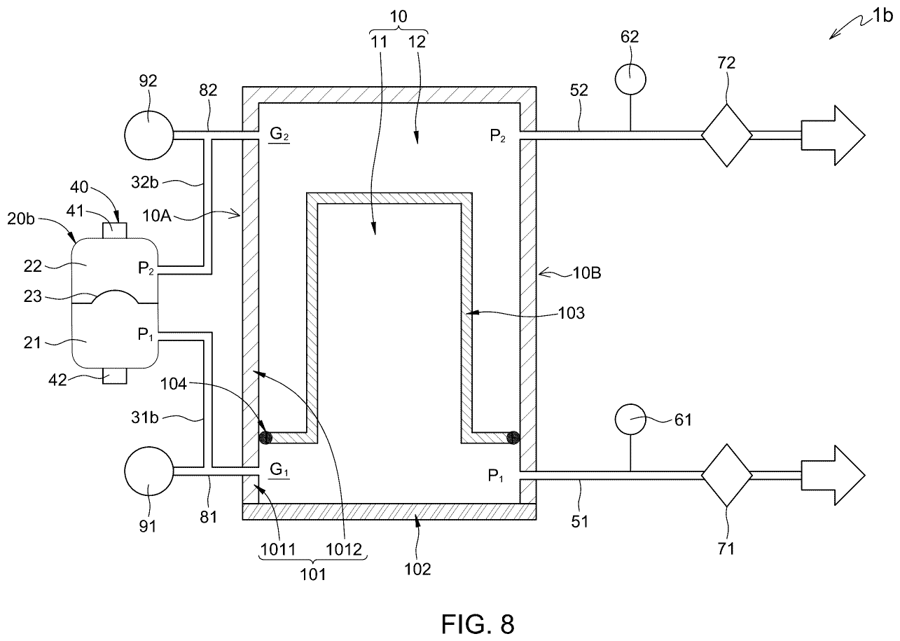

FIG. 8 illustrates a schematic view of a semiconductor equipment 1b according to some embodiments of the present disclosure. The semiconductor equipment 1b of FIG. 8 has a structure similar to the semiconductor equipment 1 of FIG. 1, except for a position of the pressure balancing element 20b in FIG. 8. In some embodiments, as shown in FIG. 8, the pressure balancing element 20b may be located at the inlet end 10A of the high-pressure processing apparatus 10. In some embodiments, the pressure balancing element 20b may be connected to the reaction gas supplying pipe 81 through the first pipe 31b and to the inert gas supplying pipe 82 through the second pipe 32b.

In some embodiments, the pressure balancing element 20b may be located within the high-pressure processing apparatus 10.

FIG. 1 to FIG. 3 and FIG. 9 illustrate a pressure control method according to some embodiments of the present disclosure. The pressure control method is accomplished by the high-pressure processing apparatus 10 and the pressure balancing element 20.

Referring to FIG. 1, the high-pressure processing apparatus 10 may be provided.

The inner chamber 11 and the outer chamber 12 of the high-pressure processing apparatus 10 may be connected by the pressure balancing element 20. In some embodiments, the pressure balancing element 20 may be connected to the inner chamber 11 through the first pipe 31 and to the outer chamber 12 through the second pipe 32.

Referring to FIG. 2, the first pressure P₁ and the second pressure P₂ may be balanced upon a pressure difference between the first pressure P₁ and the second pressure P₂ received by the pressure balancing element 20 is greater than a predetermined value. In some embodiments, the pressure balancing element 20 may have a pressure tolerance value less than a pressure tolerance value of the inner chamber 11 and the predetermined value (i.e., the predetermined pressure difference between the first pressure P₁ and the second pressure P₂). In some embodiments, the predetermined value may be greater than or equal to 0.01 bar.

In some embodiments, as shown in FIG. 2, the isolation component 23 of the pressure balancing element 20 may burst through the pressure difference to communicate the first space 21 with the second space 22 and balance the first pressure P₁ and the second pressure P₂, resulting in P₁=P₂.

Referring to FIG. 3, the isolation component 23 may be detected by the at least one detection element 40. In some embodiments, the isolation component 23 may include an intact state and a burst state. In some embodiments, the at least one detection element 40 may include a photo interrupter or a circuit component.

In some embodiments, an alarm signal may be sent to the high-pressure processing apparatus 10 upon detecting the burst state of the isolation component 23 by the at least one detection element 40.

In some embodiments, the high-pressure processing apparatus 10 may be shut down after balancing the first pressure P₁ and the second pressure P₂. In some embodiments, the high-pressure processing apparatus 10 may be shut down when the high-pressure processing apparatus 10 receives the alarm signal.

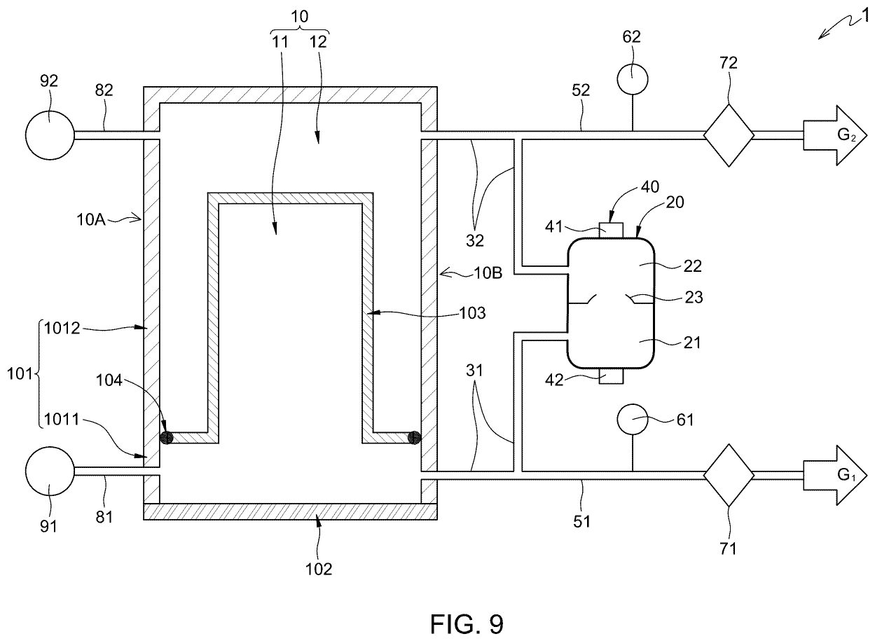

FIG. 9 illustrates a schematic view of one or more stages of some embodiments of a pressure control method according to the present disclosure. In some embodiments, as shown in FIG. 9, the reaction gas G₁ and the inert gas G₂ may be recycled through two isolated pipes (e.g., the first exhaust pipe 51 and the second exhaust pipe 52) respectively after balancing the first pressure P₁ and the second pressure P₂. In some embodiments, the first pressure control element 71 and the second pressure control element 72 may be opened during recycling the reaction gas G₁ and the inert gas G₂.

FIG. 6, FIG. 7A and FIG. 7B illustrate a pressure control method according to some embodiments of the present disclosure. The pressure control method is accomplished by the high-pressure processing apparatus 10 and the pressure balancing element 20a.

The stage illustrated in FIG. 6 is the same as, or similar to, the stage illustrated in FIG. 1, except that a structure of the isolation component 23a of the pressure balancing element 20a. Referring to FIG. 6, the isolation component 23a of the pressure balancing element 20a may include a first valve portion 231 and a second valve portion 232.

The stage illustrated in FIG. 7A or FIG. 7B is the same as, or similar to, the stage illustrated in FIG. 2, except that operations of the isolation component 23a of the pressure balancing element 20a. Referring to FIG. 7A, the first valve portion 231 may be opened through the pressure difference between the first pressure P₁ and the second pressure P₂ (e.g., P₁>P₂). Referring to FIG. 7B, the second valve portion 232 may be opened through the pressure difference between the first pressure P₁ and the second pressure P₂ (e.g., P₁<P₂). The opened first valve portion 231 or the opened second valve portion 232 may communicate the first space 21 with the second space 22 to balance the first pressure P₁ and the second pressure P₂, resulting in P₁=P₂.

The embodiments disclosed above have the following aspects, for example.

(Clause 1) A semiconductor equipment, including:
a high-pressure processing apparatus comprising:
   an inner chamber configured to accommodate a reaction gas at a first pressure; and
   an outer chamber surrounding the inner chamber and configured to accommodate an inert gas at a second pressure, wherein the outer chamber is isolated from the inner chamber in the high-pressure processing apparatus; and
a pressure balancing element connected to the inner chamber through a first pipe, connected to the outer chamber through a second pipe isolated from the first pipe, and configured to balance the first pressure and the second pressure when a pressure difference between the first pressure and the second pressure is greater than a predetermined pressure difference.

(Clause 2) The semiconductor equipment of Clause 1, wherein the pressure balancing element has a pressure tolerance value less than a pressure tolerance value of the inner chamber.

(Clause 3) The semiconductor equipment of Clause 1, wherein the pressure balancing element has a pressure tolerance value less than the predetermined pressure difference.

(Clause 4) The semiconductor equipment of Clause 3, wherein the pressure difference is greater than or equal to 0.01 bar.

(Clause 5) The semiconductor equipment of Clause 1, wherein the pressure balancing element includes a first space configured to receive the reaction gas at the first pressure, a second space configured to receive the inert gas at the second pressure, and an isolation component configured to isolate the first space from the second space.

(Clause 6) The semiconductor equipment of Clause 5, wherein the isolation component has a pressure tolerance value less than the predetermined pressure difference.

(Clause 7) The semiconductor equipment of Clause 5, further including at least one detection element disposed on the pressure balancing element and configured to detect the isolation component.

(Clause 8) The semiconductor equipment of Clause 7, wherein the isolation component includes an intact state and a burst state, and the at least one detection element sends an alarm signal to the high-pressure processing apparatus upon detecting the burst state of the isolation component.

(Clause 9) The semiconductor equipment of Clause 7, wherein the at least one detection element includes a photo interrupter.

(Clause 10) The semiconductor equipment of Clause 7, wherein the at least one detection element includes a circuit component attached to the isolation component.

(Clause 11) The semiconductor equipment of Clause 5, wherein the isolation component includes a first valve portion configured to release pressure along a first direction and a second valve portion configured to release pressure along a second direction contrary to the first direction.

(Clause 12) The semiconductor equipment of Clause 11, wherein the first valve portion or the second valve portion releases pressure when the pressure difference between the first pressure and the second pressure is greater than a pressure tolerance value of the first valve portion or a pressure tolerance value of the second valve portion.

(Clause 13) The semiconductor equipment of Clause 1, wherein the pressure balancing element includes a bursting disc, mechanical safety valve, or mechanical proportional valve.

(Clause 14) The semiconductor equipment of Clause 1, wherein the pressure balancing element is located at an outlet end of the high-pressure processing apparatus.

(Clause 15) The semiconductor equipment of Clause 1, wherein the pressure balancing element is located at an inlet end of the high-pressure processing apparatus.

(Clause 16) The semiconductor equipment of Clause 1, wherein the pressure balancing element is located within the high-pressure processing apparatus.

(Clause 17) The semiconductor equipment of Clause 1, further including;
a first exhaust pipe communicating with the first pipe and configured to exhaust the reaction gas; and
a second exhaust pipe communicating with the second pipe and configured to exhaust the inert gas, wherein the second exhaust pipe is isolated from the first exhaust pipe.

(Clause 18) The semiconductor equipment of Clause 17, further including:
a first pressure transmitting element disposed on the first exhaust pipe and configured to convert the first pressure of the reaction gas into a first electronic pressure signal; and
a second pressure transmitting element disposed on the second exhaust pipe and configured to convert the second pressure of the inert gas into a second electronic pressure signal.

(Clause 19) The semiconductor equipment of Clause 17, further including:
a first pressure control element disposed on the first exhaust pipe and configured to control the first pressure; and
a second pressure control element disposed on the second exhaust pipe and configured to control the second pressure.

(Clause 20) The semiconductor equipment of Clause 1, further including;
a reaction gas supplying pipe connected to the inner chamber from an opposite direction to the first pipe;
a first booster element disposed on the reaction gas supplying pipe and configured to boost the first pressure of the reaction gas;
an inert gas supplying pipe connected to the outer chamber from an opposite direction to the second pipe; and
a second booster element disposed on the inert gas supplying pipe and configured to boost the second pressure of the inert gas.

(Clause 21) The semiconductor equipment of Clause 1, wherein the high-pressure processing apparatus includes:
a housing;
a lid combined with the housing; and
a cover disposed in the housing;
wherein the inner chamber is defined by a first portion of the housing, the lid and the cover, and the outer chamber is defined by a second portion of the housing and the cover, wherein the pressure balancing element is configured to prevent the cover from breaking due to the pressure difference between the first pressure and the second pressure.

(Clause 22) The semiconductor equipment of Clause 21, wherein the high-pressure processing apparatus further includes at least one sealing element disposed between the housing and the cover to isolate the inner chamber from the outer chamber.

(Clause 23) A pressure control method, including:
providing a high-pressure processing apparatus including an inner chamber configured to accommodate a reaction gas at a first pressure and an outer chamber surrounding the inner chamber and configured to accommodate an inert gas at a second pressure, wherein the outer chamber is isolated from the inner chamber in the high-pressure processing apparatus;
connecting the inner chamber and the outer chamber by a pressure balancing element; and
balancing the first pressure and the second pressure upon a pressure difference between the first pressure and the second pressure received by the pressure balancing element is greater than a predetermined value.

(Clause 24) The pressure control method of Clause 23, wherein the pressure balancing element has a pressure tolerance value less than a pressure tolerance value of the inner chamber.

(Clause 25) The pressure control method of Clause 23, wherein the pressure balancing element has a pressure tolerance value less than the predetermined value.

(Clause 26) The pressure control method of Clause 25, wherein the predetermined value is greater than or equal to 0.01 bar.

(Clause 27) The pressure control method of Clause 23, wherein the pressure balancing element includes a first space configured to receive the reaction gas at the first pressure, a second space configured to receive the inert gas at the second pressure, and an isolation component configured to isolate the first space from the second space, and the balancing of the first pressure and the second pressure includes:
bursting the isolation component of the pressure balancing element through the pressure difference.

(Clause 28) The pressure control method of Clause 27, wherein the balancing of the first pressure and the second pressure further includes:
detecting the isolation component by at least one detection element.

(Clause 29) The pressure control method of Clause 28, wherein the isolation component includes an intact state and a burst state, and after the balancing of the first pressure and the second pressure, the method further includes:
sending an alarm signal to the high-pressure processing apparatus upon detecting the burst state of the isolation component by the at least one detection element.

(Claus 30) The pressure control method of Clause 23, wherein the pressure balancing element includes a first space configured to receive the reaction gas at the first pressure, a second space configured to receive the inert gas at the second pressure, and an isolation component configured to isolate the first space from the second space, the isolation component includes a first valve portion configured to release pressure along a first direction and a second valve portion configured to release pressure along a second direction contrary to the first direction, and the balancing of the first pressure and the second pressure includes:
opening the first valve portion or the second valve portion through the pressure difference.

(Clause 31) The pressure control method of Clause 23, wherein after the balancing of
the first pressure and the second pressure, the method further includes:
shutting down the high-pressure processing apparatus.

(Clause 32) The pressure control method of Clause 23, wherein after the balancing of the first pressure and the second pressure, the method further includes:
Recycling the Reaction Gas and the Inert Gas Through Two Isolated Pipes Respectively.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor equipment, comprising:
a high-pressure processing apparatus comprising:
an inner chamber configured to accommodate a reaction gas at a first pressure; and
an outer chamber surrounding the inner chamber and configured to accommodate an inert gas at a second pressure, wherein the outer chamber is isolated from the inner chamber in the high-pressure processing apparatus; and
a pressure balancing element connected to the inner chamber through a first pipe, connected to the outer chamber through a second pipe isolated from the first pipe, and configured to balance the first pressure and the second pressure when a pressure difference between the first pressure and the second pressure is greater than a predetermined pressure difference.

2. The semiconductor equipment of claim 1, wherein the pressure balancing element has a pressure tolerance value less than a pressure tolerance value of the inner chamber.

3. The semiconductor equipment of claim 1, wherein the pressure balancing element has a pressure tolerance value less than the predetermined pressure difference.

4. The semiconductor equipment of claim 3, wherein the pressure difference is greater than or equal to 0.01 bar.

5. The semiconductor equipment of claim 1, wherein the pressure balancing element includes a first space configured to receive the reaction gas at the first pressure, a second space configured to receive the inert gas at the second pressure, and an isolation component configured to isolate the first space from the second space.

6. The semiconductor equipment of claim 5, wherein the isolation component has a pressure tolerance value less than the predetermined pressure difference.

7. The semiconductor equipment of claim 5, further comprising at least one detection element disposed on the pressure balancing element and configured to detect the isolation component.

8. The semiconductor equipment of claim 7, wherein the isolation component includes an intact state and a burst state, and the at least one detection element sends an alarm signal to the high-pressure processing apparatus upon detecting the burst state of the isolation component.

9. The semiconductor equipment of claim 7, wherein the at least one detection element includes a photo interrupter.

10. The semiconductor equipment of claim 7, wherein the at least one detection element includes a circuit component attached to the isolation component.

11. The semiconductor equipment of claim 5, wherein the isolation component includes a first valve portion configured to release pressure along a first direction and a second valve portion configured to release pressure along a second direction contrary to the first direction.

12. The semiconductor equipment of claim 11, wherein the first valve portion or the second valve portion releases pressure when the pressure difference between the first pressure and the second pressure is greater than a pressure tolerance value of the first valve portion or a pressure tolerance value of the second valve portion.

13. The semiconductor equipment of claim 1, wherein the pressure balancing element includes a bursting disc, mechanical safety valve, or mechanical proportional valve.

14. The semiconductor equipment of claim 1, wherein the pressure balancing element is located at an outlet end of the high-pressure processing apparatus.

15. The semiconductor equipment of claim 1, wherein the pressure balancing element is located at an inlet end of the high-pressure processing apparatus.

16. The semiconductor equipment of claim 1, wherein the pressure balancing element is located within the high-pressure processing apparatus.

17. The semiconductor equipment of claim 1, further comprising;
a first exhaust pipe communicating with the first pipe and configured to exhaust the reaction gas; and
a second exhaust pipe communicating with the second pipe and configured to exhaust the inert gas, wherein the second exhaust pipe is isolated from the first exhaust pipe.

18. The semiconductor equipment of claim 17, further comprising:
a first pressure transmitting element disposed on the first exhaust pipe and configured to convert the first pressure of the reaction gas into a first electronic pressure signal; and
a second pressure transmitting element disposed on the second exhaust pipe and configured to convert the second pressure of the inert gas into a second electronic pressure signal.

19. The semiconductor equipment of claim 17, further comprising:
a first pressure control element disposed on the first exhaust pipe and configured to control the first pressure; and
a second pressure control element disposed on the second exhaust pipe and configured to control the second pressure.

20. The semiconductor equipment of claim 1, further comprising;
a reaction gas supplying pipe connected to the inner chamber from an opposite direction to the first pipe;
a first booster element disposed on the reaction gas supplying pipe and configured to boost the first pressure of the reaction gas;
an inert gas supplying pipe connected to the outer chamber from an opposite direction to the second pipe; and
a second booster element disposed on the inert gas supplying pipe and configured to boost the second pressure of the inert gas.
